(19) United States
(12) Patent Application Publication
(10) Pub. No.: US 2007/0111398 A1
(43) Pub. Date: May 17, 2007

(54) Micro-electronic package structure and method for fabricating the same

(75) Inventor: Shih-Ping Hsu, Hsin-chu (TW)

Correspondence Address: CLARK & BRODY, 1090 VERMONT AVENUE, NW, SUITE 250, WASHINGTON, DC, 20005, US

(73) Assignee: PHOENIX PRECISION CORPORATION

(21) Appl. No.: 11/650,448

(22) Filed: Jan. 8, 2007

Related U.S. Application Data
(62) Division of application No. 11/008,972, filed on Dec. 13, 2004.

(30) Foreign Application Priority Data
Sep. 1, 2004 (TW) 093126323

(51) Int. Cl. H01L 21/00

(52) U.S. Cl. 438/125

(57) ABSTRACT

A micro-electronic package structure and a method for fabricating the same are proposed. A carrier is prepared and provided with a cavity for receiving at least one semiconductor chip having a plurality of electrical connection contacts. A dielectric layer is formed on the carrier, with the electrical connection contacts being exposed from the dielectric layer. A first circuit layer is formed on the dielectric layer and electrically connected to a portion of the electrical connection contacts of the chip. Another dielectric layer is formed on the first circuit layer and said dielectric layer, and a second circuit layer is formed on this dielectric layer and electrically connected to the rest of the electrical connection contacts of the chip and the first circuit layer by conductive vias, such that the chip is integrated into the carrier.

### FIELD OF THE INVENTION

The present invention relates to micro-electronic package structures and methods for fabricating the same, and more particularly to a circuit board integrated with a semiconductor chip, and a method for fabricating the circuit board structure.

### BACKGROUND OF THE INVENTION

As the semiconductor packaging technology advances, there have been developed many different types of semiconductor packages. One of the advanced semiconductor packages is referred to as ball grid array (BGA) package, which is characterized in using a substrate for accommodating a chip on a front surface thereof, and implanting a plurality of array-arranged solder balls on a back surface of the substrate via a self-alignment technique. This arrangement allows relatively more solder balls to be incorporated on a unit area of the substrate acting as a chip carrier, which is desirable for a highly integrated semiconductor chip, and the solder balls serve as I/O (input/output) connections to bond and electrically connect the entire package to an external printed circuit board.

Flip-chip packaging technology has been introduced by IBM Company since early 1960's. Compared to wire-bonding technology, the flip-chip packaging technique is characterized in using solder bumps, instead of gold wires, to electrically connect a semiconductor chip and a substrate in the package, which is advantageous to increase the packaging density while reducing the package size. Moreover, the flip-chip package does not need long metal wires and thus has improved electric performance, thereby satisfying the requirement for high density and high operation speed of a semiconductor device.

In a conventional flip-chip package, a plurality of electrode pads are formed on a surface of a semiconductor chip, and a plurality of corresponding contact pads are formed on a circuit board that accommodates the chip. Solder bumps or other conductive adhesive material can be applied between the chip and the circuit board, so as to allow the chip to be mounted on the circuit board in a face-down manner that an active surface of the chip faces the circuit board, and establish electrical connection between the electrode pads of the chip and the contact pads of the circuit board as well as establish mechanical connection between the chip and the circuit board.

Referring to FIGS. 1A and 1B showing a conventional flip-chip package, a plurality of metal bumps 11 are formed on electrode pads 12 of a chip 13, and a plurality of pre-solder bumps 14 made of a solder material are formed on contact pads 15 of a circuit board 16. At a temperature sufficient to melt the pre-solder bumps 14, the pre-solder bumps 14 are reflow-soldered to the corresponding metal bumps 11 to form solder joints 17. An organic underfill material 18 may be used to fill a gap between the chip 13 and the circuit board 16, which provides a buffer effect to diminish the mismatch of thermal expansion between the chip 13 and the circuit board 16 and also reduce the stress of the solder joints 17.

Recently, the solder material is deposited on the contact pads of the circuit board to form the pre-solder bumps by stencil printing technology. However, in practice, due to the great development of various portable products in the fields of communication, networking and computing, BGA packages, chip size packages (CSPs) and multi chip modules (MCMs), etc., which can reduce the chip area and have high density of contact leads, have become mainstream products in the package market. These packages are often cooperative with high performance chips such as microprocessors, chip sets and graphic chips to achieve higher operational speed. However, in such packages, both the width of circuits and the size of pads are miniaturized. With a pitch distance between adjacent pads being decreased, an insulating protective layer formed over the surface of the circuit board would partly cover the pads and make the surface area of the pads exposed from the protective layer further reduced. This not only cause an alignment problem for subsequently forming pre-solder bumps on the pads, but also makes stencil cavitys being reduced in size thereby causing the solder material difficult to deposit on the pads (contact pads) due to the space occupied by the protective layer. As a result, the stencil printing technique would have extremely low yield and cannot be employed. Moreover, the cost of the stencil is increased due to reduction of pad size and pad pitch, making the overall fabrication cost raised. Furthermore, with the pitch distance between the adjacent pads being reduced, the contact surface area between the protective layer and the circuit board becomes even smaller, thereby diminish the adhesion between the protective layer and the circuit board.

Furthermore, in the fabricating processes of a flip-chip semiconductor package, after forming wafer integrated circuits, a under bump metallurgy (UBM) structure is formed on each of the electrode pads of the wafer chip for carrying a metal bump. A dicing process is performed to divide the wafer into individual chips. Then, the chip is mounted and electrically connected to a circuit board in a flip-chip manner. The fabrication processes of the UBM structures and the metal bumps include forming a passivation layer on the wafer, with the electrode pads being exposed from the passivation layer. Sputtering and electroplating processes are subsequently performed to form UMB structures each comprising multiple metal layers. Then, a solder mask layer is applied on the passivation layer and has a plurality of openings for exposing the UMB structures. Subsequently, a solder material such as Sn/Pb alloy is applied on the UBM structures through the openings of the solder mask layer using the stencil printing technique. Then, a reflow process is performed such that the solder material is reflow-soldered to the UBM structures. After that, the solder mask layer is removed, and a second reflow process is performed to make the solder material become metal bumps formed on the wafer, such that the chip can be electrically connected to the circuit board via the metal bumps.

Accordingly, with regard to the flip-chip semiconductor package, it needs to form corresponding electrical connection means such as metal bumps or pre-solder bumps respectively on the semiconductor chip and the circuit board. This not only increases the fabrication process complexity and cost, but also leads to the reliability concern.

Regardless of the use of the flip-chip packaging technology or the wire-bonding packaging technology, fabrication of the circuit board and packaging of the semiconductor chip require different machines and procedures, thereby making the fabrication processes very complicated and costly. Moreover, in a molding process that the circuit board mounted with the chip is placed in a mold, an epoxy resin is injected into the mold to form an encapsulation body for encapsulating the chip. However, in practice, the mold is often limited to a particular design of the semiconductor package, such that the size of a molding cavity and the clamping positions may bear structural differences and are not able to tightly clamp the circuit board. When the epoxy resin in injected into the molding cavity, these differences may lead to a resin flash problem that resin may flash to the surface of the circuit board. As a result, the surface planarity and appearance of the semiconductor package would both be damaged, and ball pads on the circuit board for subsequently bonding solder balls may be contaminated, such that the quality of electrical connection as well as the yield and reliability of the semiconductor package are seriously degraded.

In the general fabrication processes of a semiconductor device, firstly suitable chip carriers for the semiconductor device are prepared by via a carrier manufacturer (such as circuit board manufacturer). Then, the chip carriers are transferred to a semiconductor packaging manufacturer and subjected to die-bonding, molding, and ball implanting processes, etc., so as to produce the semiconductor device having electric functions required by a client. Since the fabrication processes of the semiconductor device involve a number of different manufacturers, including the carrier manufacturer and the semiconductor packaging manufacturer, the fabrication processes are complicated in practice and not easy to achieve interface integration. In case the client wishes to modify the product design, the changes and integration involved are even more complicated, not meeting the requirements of flexibility in change and economical benefit.

### SUMMARY OF THE INVENTION

In accordance with the above drawbacks in the prior art, an objective of the present invention is to provide a micro-electronic package structure and a method for fabricating the same, which can integrate of fabrication processes of a chip carrier and semiconductor packaging processes so as to provide greater flexibility in response to the client's requirements as well as simplify fabricating processes of a semiconductor package and the problem of interface integration.

Another objective of the present invention is to provide a micro-electronic package structure and a method for fabricating the same, which can avoid the problems in the prior art caused by inappropriate electrical connection between a semiconductor chip and a circuit board.

Still another objective of the present invention is to provide a micro-electronic package structure and a method for fabricating the same, which can simplify the processes of integrating a chip into a circuit board, thereby reducing the process complexity and fabrication cost.

A further objective of the present invention is to provide a micro-electronic package structure and a method for fabricating the same, which can eliminate the resin flash problem in the prior art, so as to effectively improve the production yield and product reliability.

In order to solve the foregoing and other objectives, the present invention proposes a method for fabricating a micro-electronic package structure, comprising the steps of: preparing a carrier (such as a general carrier or a circuit board) with at least one cavity for receiving at least one semiconductor chip; mounting at least one semiconductor chip having a plurality of electrical connection contacts in the cavity of the carrier; forming a first dielectric layer on the carrier, with the electrical connection contacts being exposed from the first dielectric layer; forming a first circuit layer on the first dielectric layer, and electrically connecting the first circuit layer to a portion of the electrical connection contacts of the chip; forming a second dielectric layer on the first circuit layer; and forming a second circuit layer on the second dielectric layer, and electrically connecting the second circuit layer to the rest of the electrical connection contacts of the chip and the first dielectric layer. The electrical connection contacts of the chip includes electrode pads and conductive bumps formed on the electrode pads, so as to allow subsequent circuits to be electrically connected to the chip via the electrical connection contacts.

By the above fabrication method, the present invention also proposes a micro-electronic package structure, comprising: a carrier, such as a typical carrier or a circuit board, having at least one cavity; at least one semiconductor chip having a plurality of electrical connection contacts and received in the cavity of the carrier; a first dielectric layer formed on the carrier and covering the cavity; a first circuit layer formed on the first dielectric layer and electrically connected to a portion of the electrical connection contacts of the chip; a second dielectric layer formed on the first circuit layer; and a second circuit layer formed on the second dielectric layer and electrically connected to the rest of the electrical connection contacts of the chip via conductive vias formed through the first and second dielectric layers.

Since conventionally electrode pads are usually arranged too densely on an active surface of a chip, it would be difficult to form outwardly extending circuits from the electrode pads. Accordingly, the present invention proposes an electrical connection structure of a micro-electronic package structure, comprising: an electrode pad disposed on an active surface of a semiconductor chip that is received in a cavity of a carrier in the micro-electronic package structure; a conductive bump formed on the electrode pad; and a conductive via formed on the conductive bump, for electrically connecting the electrode pad of the chip to a circuit layer of the carrier via the conductive bump and the conductive via.

Therefore, according to the micro-electronic package structure and the fabrication method thereof in the present invention, at least one semiconductor chip having a plurality of electrode pads formed on at least one surface thereof is provided and received in a cavity of a carrier, with a conductive bump formed on each of the electrode pads. This arrangement can reduce the overall thickness of the package structure in favor of size miniaturization. Moreover, in the present invention, a dielectric layer is formed on the carrier receiving the chip, and conductive structures are formed in the dielectric layer and electrically connected to electrical connection contacts (including the electrode pads and conductive bumps) of the chip, such that the electrical connection contacts of the chip are electrically extended via the conductive structure. This combines the fabrication processes of a chip carrier and the semiconductor packaging processes, thereby providing better flexibility to meet the client's requirements and simplifying the overall fabrication processes as well as solving the problems of interface integration, inappropriate electrical connection and molding encountered in the prior art.

Furthermore, in response to the problem in the prior art that not all electrode pads of a chip can be electrically extended since they are too densely arranged, the present invention provides a solution by firstly allowing a portion of the electrode pads of the chip to be electrically connected to the first circuit layer via conductive bumps formed on the electrode pads, and allowing the rest of the electrode pads to be electrically connected to the second circuit layer via the conductive bumps and conductive structures formed through the dielectric layers, such that electrical connection between the chip and the carrier or circuit board can be established.

### BRIEF DESCRIPTION OF THE DRAWINGS

The present invention can be more fully understood by reading the following detailed description of the preferred embodiments, with reference made to the accompanying drawings, wherein:

FIGS. 1A and 1B (PRIOR ART) are schematic cross-sectional diagrams showing a conventional flip-chip semiconductor package;

FIGS. 2A to 2F are schematic cross-sectional diagrams showing procedural steps of a method for fabricating a micro-electronic package structure in accordance with the present invention;

FIG. 2C′ is a schematic cross-sectional view of forming exposed electrical connection contacts on the chip in the method for fabricating a micro-electronic package structure in accordance with the present invention; and

FIG. 2D′ is a schematic cross-sectional view of establishing electrical connection between conductive bumps via a first circuit layer in the method for fabricating a micro-electronic package structure in accordance with the present invention.

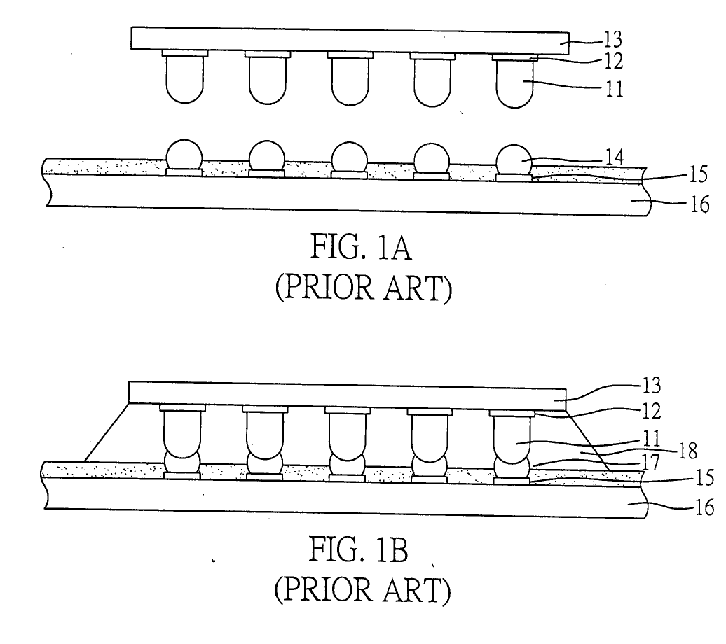

### DETAILED DESCRIPTION OF THE PREFERRED EMBODIMENTS

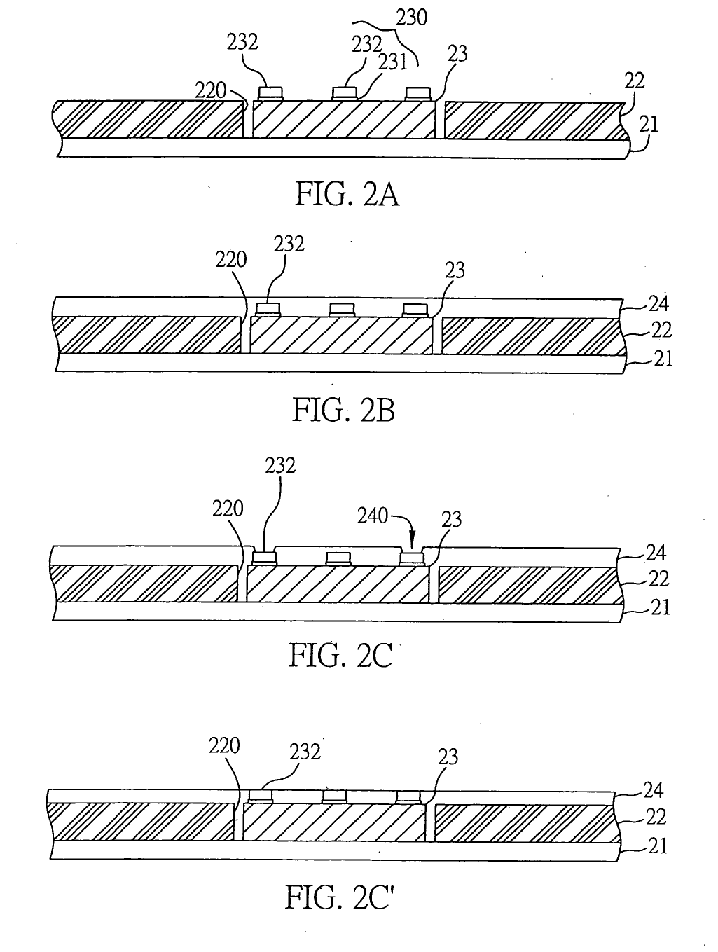

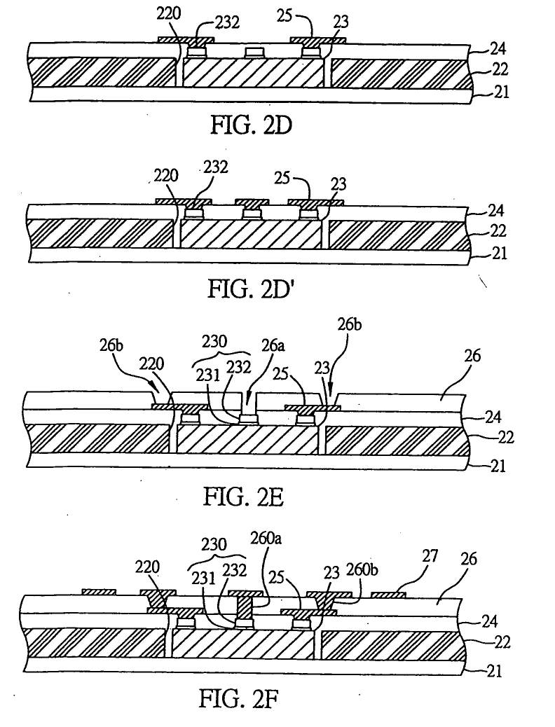

FIGS. 2A to 2F show the procedural steps of a method for fabricating a micro-electronic package structure in accordance with the present invention.

Referring to FIG. 2A, a carrier 22 is provided, which can be a metal board, insulating board, or circuit board. The carrier 22 is formed with at least one cavity 220 therethrough. A supporting member 21 may be attached on one side of the carrier 22 and covers one end of the cavity 220. This supporting member 21 can be an adhesive layer or a metal layer, which allows at least one semiconductor chip 23 to be mounted the supporting member 21 and received in the cavity 220 of the carrier 22, wherein electrical connection contacts 230 formed on an active surface of the chip 23 are exposed to the cavity 220. The electrical connection contacts 230 of the chip 23 comprise electrode pads 231 and conductive bumps 232 formed on the electrode pads 231, and are used to establish good external electrical connection for the chip 23.

Referring to FIG. 2B, a first dielectric layer 24 is formed on the carrier 22 and the chip 23 and fills the cavity 220 of the carrier 22. The first dielectric layer 24 can be made of a fiber-enhanced resin, polyphenol ester, epoxy resin or photo-imageable resin.

Referring to FIG. 2C, a plurality of openings 240 are formed in the first dielectric layer 24 using a laser drilling technique or an exposure and developing technique for a photo-imageable resin, so as to expose the conductive bumps 232 on the active surface of the chip 23. Alternatively, it is applicable to only form a portion of openings in the dielectric layer for a circuit layer to be subsequently formed thereon, and leave areas on the dielectric layer, where circuits are not to be formed due to densely arranged electrical connection contacts, not having the openings.

Alternatively, as shown in FIG. 2C′, a thinning technique such as plasma etching or publishing can be used to thin the first dielectric layer 24 until exposing the upper surface of conductive bumps 232 of the chip 23.

Referring to FIG. 2D, a first circuit layer 25 is formed on the first dielectric layer 24 and electrically connected to a portion of the conductive bumps 232 of the chip 23, such that there are formed circuits outwardly extended from the conductive bumps 232. The first circuit layer 25 can be fabricated by in turn forming a conductive layer and a patterned resist layer (not shown) on the first dielectric layer 24 and in the openings 240, the resist layer having a plurality of openings for exposing a portion of the underlying conductive layer, and performing an electroplating process to deposit the first circuit layer 25 such as a copper layer on the dielectric layer 24. For some of the conductive bumps 232 that are too densely arranged, there would be no circuit extended from these conductive bumps 232. Then, the resist layer and the conductive layer covered by the resist layer are removed. On the other hand, as shown in FIG. 2D′, if there is a sufficient pitch distance between adjacent electrode pads 231 of the chip 23, it allows the first circuit layer 25 to be electrically connected to all the conductive bumps 232.

Referring to FIG. 2E, a second dielectric layer 26 is formed on the first circuit layer 25 and the first dielectric layer 24. The second dielectric layer 26 has a plurality of openings 26a penetrating both the first and second dielectric layers 24, 26 to expose the rest of the conductive bumps 232 of the chip 23 that are not electrically connected to the first circuit layer 25, and a plurality of openings 26b for exposing a portion of the first circuit layer 25.

Referring to FIG. 2F, similarly, a conductive layer and a patterned resist layer (not shown) are in turn formed on the second dielectric layer 26, wherein the resist layer has a plurality of openings for exposing a portion of the underlying conductive layer. An electroplating process is performed to deposit a second circuit layer 27 on the second dielectric layer 26 and form first conductive vias 260a and second conductive vias 260b respectively in the opening 26a, 26b of the second dielectric layer 26. This allows the second circuit layer 27 to be electrically connected by the first conductive vias 260a to the rest of the conductive bumps 232 that are not electrically connected to the first circuit layer 25, and allows the second circuit layer 27 to be electrically connected to the first circuit layer 25 by the second conductive vias 260b. Then, the resist layer and the conductive layer covered by the resist layer are removed. It is applicable to subsequently continue the circuit build-up process on the carrier 22, so as to form a multi-layer circuit structure on the carrier 22 incorporated with the chip 23. This circuit build-up process is well known in the art and not to be further detailed here. The circuit build-up process can also be carried out on the two sides of the carrier.

Further referring to FIG. 2F, the present invention also discloses a micro-electronic package structure, comprising: a carrier 22, such as a general carrier or a circuit board, having at least one cavity 220; at least one semiconductor chip 23 having a plurality of electrode pads 231 and received in the cavity 220, wherein a conductive bump 232 is formed on each of the electrode pads 231; a first dielectric layer 24 formed on the carrier 22 and filling the cavity 220; a first circuit layer 25 formed on the first dielectric layer 24 and electrically connected to a portion of the conductive bumps 232 of the chip 23; a second dielectric layer 26 formed on the first circuit layer 25; and a second circuit layer 27 formed on the second dielectric layer 26 and electrically connected to the rest of the conductive bumps 232 of the chip 23 by first conductive vias 260a formed through the first dielectric layer 24 and the second dielectric layer 26.

Since electrode pads are too densely arranged on an active surface of a general chip, it is difficult to form circuits directly extended outwardly from all the electrode pads. Accordingly, in the use of the micro-electronic package structure and the fabrication method thereof in the present invention, for those electrode pads 231 not able to form circuits directly extended therefrom, conductive bumps 232 may be formed on the electrode pads 231, and then conductive vias 260a are formed on the conductive bumps 232, such that a circuit layer 27 would be formed and electrically extended from the electrode pads 231 via the conductive bumps 232 and the conductive vias 260a, thereby establishing external electrical connection for the chip.

Therefore, according to the micro-electronic package structure and the fabrication method thereof in the present invention, at least one semiconductor chip having a plurality of electrode pads formed on at least one surface thereof is provided and received in a cavity of a carrier, with a conductive bump formed on each of the electrode pads. This arrangement can reduce the overall thickness of the package structure in favor of size miniaturization. Moreover, in the present invention, a dielectric layer is formed on the carrier receiving the chip, and conductive structures are formed in the dielectric layer and electrically connected to electrical connection contacts (including the electrode pads and conductive bumps) of the chip, such that the electrical connection contacts of the chip are electrically extended via the conductive structure. This combines the fabrication processes of a chip carrier and the semiconductor packaging processes, thereby providing better flexibility to meet the client's requirements and simplifying the overall fabrication processes as well as solving the problems of interface integration, inappropriate electrical connection and molding encountered in the prior art.

Furthermore, in response to the problem in the prior art that not all electrode pads of a chip can be electrically extended since they are too densely arranged, the present invention provides a solution by firstly allowing a portion of the electrode pads of the chip to be electrically connected to the first circuit layer via conductive bumps formed on the electrode pads, and allowing the rest of the electrode pads to be electrically connected to the second circuit layer via the conductive bumps and conductive structures formed through the dielectric layers, such that electrical connection between the chip and the carrier or circuit board can be established.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method for fabricating a micro-electronic package structure, comprising the steps of:
preparing a carrier with at least one cavity for receiving at least one semiconductor chip;
mounting at least one semiconductor chip having a plurality of electrode pads in the cavity of the carrier, wherein a conductive bump is formed on each of the electrode pads;
forming a first dielectric layer on the carrier, with the conductive bumps being exposed from the first dielectric layer; and
forming a first circuit layer on the first dielectric layer, and electrically connecting the first circuit layer to the conductive bumps of the chip.

2. The method of claim 1, wherein the first circuit layer is electrically connected to a portion of the conductive bumps of the chip, and wherein a second dielectric layer is formed on the first circuit layer and the first dielectric layer, and a second circuit layer is formed on the second dielectric layer, allowing the second circuit layer to be electrically connected to the rest of the conductive bumps of the chip by conductive vias formed through the first and second dielectric layers.

3. The method of claim 1, further comprising forming at least one build-up circuit structure on the first circuit layer and electrically connecting the build-up circuit structure to the first circuit layer.

4. The method of claim 2, further comprising forming at least one build-up circuit structure on the second circuit layer and electrically connecting the build-up circuit structure to the second circuit layer.

5. The method of claim 3, wherein the build-up circuit structure comprises a dielectric layer, a circuit layer formed on the dielectric layer, and conductive vias provided in the dielectric layer.

6. The method of claim 4, wherein the build-up circuit structure comprises a dielectric layer, a circuit layer formed on the dielectric layer, and conductive vias provided in the dielectric layer.

7. The method of claim 1, wherein the carrier is one selected from the group consisting of a metal board, insulating board, and circuit board.

8. The method of claim 1, further comprising mounting a supporting member on one side of the carrier to cover one end of the cavity, such that the chip is supported on the supporting member.

9. The method of claim 8, wherein the supporting member is an adhesive layer.

10. The method of claim 1, wherein a laser drilling technique is employed to form a plurality of openings in the first dielectric layer at positions corresponding to the conductive bumps of the chip, such that the conductive bumps are exposed via the openings.

11. The method of claim 1, wherein an exposure and developing technique is employed to form a plurality of openings in the first dielectric layer at positions corresponding to the conductive bumps of the chip, such that the conductive bumps are exposed via the openings.

12. The method of claim 1, wherein a thinning technique is employed to thin the first dielectric layer so as to expose the conductive bumps of the chip.

13. The method of claim 12, wherein the thinning technique is a plasma etching technique.

14. The method of claim 1, wherein a gap between the cavity of the carrier and the chip is filled with the first dielectric layer.

15. The method of claim 1, wherein a fabrication process of the first circuit layer comprises the steps of:
forming a conductive layer on the first dielectric layer and the conductive bumps of the chip that are exposed from the first dielectric layer;
forming a patterned resist layer on the conductive layer; and
performing an electroplating process to form the first circuit layer being patterned on the conductive layer.

16. The method of claim 2, wherein a fabrication process of the second circuit layer comprises the steps of:
forming a plurality of openings in the second dielectric layer to expose a portion of the underlying first circuit layer and a portion of the underlying conductive bumps of the chip;
forming a conductive layer on the second dielectric layer and in the openings of the second dielectric layer;
forming a patterned resist layer on the conductive layer; and
performing an electroplating process to form the second circuit layer being patterned on the conductive layer.

17.-24. (canceled)
